(19) United States
(12) Patent Application Publication
(10) Pub. No.: US 2001/0055840 A1
(43) Pub. Date: Dec. 27, 2001

(54) METHOD FOR FABRICATING NARROW METAL INTERCONNECTS IN AN INTEGRATED CIRCUIT USING HEAT AND PRESSURE TO EXTRUDE A METAL LAYER INTO A LEAD TRENCH AND VIA/CONTACT

(76) Inventor: DOUGLAS P VERRET, FORT BEND COUNTY, TX (US)

Correspondence Address: TEXAS INSTRUMENTS INCORPORATED, P O BOX 655474, M/S 3999, DALLAS, TX, 75265

(21) Appl. No.: 09/216,220

(22) Filed: Dec. 18, 1998

Related U.S. Application Data
(60) Provisional application No. 60/068,278, filed on Dec. 19, 1997.

(51) Int. Cl. H01L 21/335

(52) U.S. Cl. 438/142

(57) ABSTRACT

A method for making an integrated circuit includes the step of fabricating a nonconductive layer (22, 23, 27, 29) having therein a lead trench (41) and having therethrough a via channel (36) which communicates with the lead trench. A liner (46) is applied on the nonconductive layer, a metal layer (47) is applied on the liner, and then heat and pressure are applied to extrude the metal layer into the lead trench and the via channel. A planarizing process is thereafter carried out to remove portions of the metal layer and the liner so as to create a planar surface (51) that includes coplanar surface portions on the nonconductive layer and on a portion of the metal layer remaining in the lead trench. The nonconductive layer may be fabricated by forming two dielectric layers which have therebetween an etch stop layer with openings, and then simultaneously etching both of the dielectric layers.

### BACKGROUND OF THE INVENTION

The amount of circuitry which can be implemented in an integrated circuit has been progressively increasing. As a result, there is a need to fabricate circuitry within an integrated circuit on increasingly smaller scales. One aspect of this is the need to fabricate metal interconnects with increasingly smaller pitches, or in other words metal leads with increasingly smaller widths, and increasingly smaller spaces between adjacent leads. More specifically, technology has reached a point where it is desirable to fabricate metal interconnects which are less than 0.5 micron in width. This includes not only the leads on a given lead level, but also the vias which interconnect lead levels.

A conventional and widely-used technique for fabricating vias is commonly known as tungsten-plug or W-plug technology. A dielectric layer is formed, a photoresist is applied to a dielectric layer, and an etching step is carried out to etch via channels through the dielectric layer in a pattern which is defined by the photoresist. The photoresist is then removed, and a barrier layer is applied on the dielectric and in the via channels, the barrier layer promoting adhesion and serving as a diffusion barrier. The barrier layer is also commonly referred to as a liner.

Tungsten is then deposited on the liner and in the via channels, and then is etched down so that only the portions in the via channels are left, thus leaving tungsten “plugs” in the via channels. The resulting structure is then thoroughly cleaned. Thereafter, a layer of a metal or a metal alloy, typically aluminum or an aluminum alloy, is applied over the barrier layer and the upper ends of the tungsten plugs. This metal layer is then etched to form a desired pattern of interconnects or leads between the tungsten plugs.

Sometimes, an optional second barrier layer is applied over the first barrier layer and the plugs, before applying the metal layer. Alternatively, an optional anti-reflective coating (ARC) may be provided over the metal layer before it is etched, in order to avoid undesired reflections when the photoresist is exposed to light in preparation for etching the metal layer.

While this conventional technique has been generally adequate for its intended purposes, it has not been satisfactory in all respects. More specifically, when this conventional technique is used to form interconnects which have widths less than 0.5 micron, the reliability of the metal leads decreases.

In the case of vias, the thickness of the dielectric remains about the same even though the via widths are decreased. This is sometimes referred to as an increase in the aspect ratio (height over width) of the vias. Where vias have a width which is less than 0.5 micron, there is an increased tendency for the vias to heat up when exposed to a high current density, which in turn can cause the aluminum leads in contact with the vias to physically move in a manner creating a physical gap that interrupts the current flow. This is known as an electromigration failure.

Although it may be possible to reduce electromigration failures in this context by using different materials, by adding dopants, or by using a more complex process, these all lead to increased costs and reduced reliability, which are generally undesirable in the integrated circuit manufacturing industry. Another drawback is that, when interconnect widths are less than about 0.25 micron, a via in one lead level is typically not positioned so as to be vertically aligned with a via in another lead level immediately above it or below it, because the resulting structure is less reliable than if the vias are transversely offset from each other.

As discussed above, the pattern of leads in the conventional technique is formed by applying a metal layer, and then etching away undesired portions of the metal layer. A known alternative is called damascence. In damascence, a nonconductive layer such a dielectric is fabricated, lead trenches are then created in the dielectric, metal is deposited in the lead trenches, and any excess metal is physically removed, for example through a chemical mechanical polishing. A known variation of this is double damascence, where both the lead trenches and the via channels are formed in a nonconductive layer, for example by carrying out two etch steps with separate photoresists to respectively form the via channels and the lead trenches, after which a metal layer is deposited into both the via channels and the lead trenches. However, neither form of damascence has been widely used for actual manufacturing of integrated circuits, in part because of difficulties in attempting to reliably deposit metal into both the via channels and the lead trenches using standard deposition techniques. Further, two separate etch steps must be performed on the dielectric to respectively create the via channels and the lead trenches, and the etching to create the lead trenches must be carefully controlled in order to ensure that the lead trenches have a desired depth and that this desired depth is reasonably uniform throughout the lead trenches.

With respect to electromigration, it is known that electromigration failures decrease when a metal layer is applied and then subjected to heat and pressure in order to introduce portions of the metal layer into vias. This technique, which is referred to herein as extrusion, is described in “A Novel High Pressure Low Temperature Aluminum Plug Technology For Sub-0.5 μm Contact/Via Geometries” by Dixit et al, IEDM 94, pages 105-108, 1994. Although it is not clear why this extrusion technique reduces electromigration failures, it is known that the aluminum extruded into the vias at elevated temperatures of 300° C.-500° C. has long columnar grains, and it is believed that these long columnar grains may possibly contribute to the reduction in electromigration failures. Further, there is speculation that the long columnar grains may tend to have a particular crystal orientation, and that such an orientation, if present, may possibly contribute to the reduced electromigration failures. This extrusion process has been used in place of the conventional plug technology to create vias, and has been used in place of conventional etching techniques to create leads, but is not known to have been used to simultaneously create both leads and vias which are integral with each other, in part because the conventional plug technology inherently involves separate creation of the via “plugs” and the metal leads.

### SUMMARY OF THE INVENTION

From the foregoing, it may be appreciated that a need has arisen for a method of fabricating an integrated circuit having narrow metal interconnects which reliably resist electromigration failure. According to the present invention, a method is provided to address this need, and involves the steps of: fabricating on a substrate structure a nonconductive layer having in a side thereof opposite from the substrate structure a lead trench which is spaced from the substrate structure, and having a via channel which opens at one end into the lead trench and which opens at the other end through a side of the nonconductive layer nearest the substrate structure; applying on a side of the nonconductive layer opposite from the substrate structure a liner, the liner covering exposed surfaces in the lead trench and the via channel; applying on a side of the liner opposite from the substrate structure a metal layer; simultaneously applying heat and pressure so as to cause the metal layer to be extruded into and to fill the lead trench and the via opening; and thereafter carrying out a planarizing step which creates a substantially planar first surface portion on a side of the nonconductive layer opposite from the substrate structure, which removes portions of the substrate structure and the metal layer on a side of the first surface portion remote from the substrate structure, and which creates on a portion of the metal layer disposed in the lead trench a second surface portion which is substantially coplanar with the first surface portion. The invention also encompasses an integrated circuit made by this method.

Further, it will be appreciated that a need has arisen for a method of fabricating an integrated circuit in which a double damascence technique can be used with only a single dielectric etch step. According to the present invention, a method is provided to address this need, and involves the steps of: forming a first dielectric layer on a surface of a base structure; forming on the first dielectric layer an etch stop layer; forming in the etch stop layer an opening; forming on the etch stop layer a second dielectric layer; and etching the first and second dielectric layers so as to create in the second dielectric layer a lead trench and so as to create through the first dielectric layer an opening aligned with the opening through the etch stop layer, the openings through the etch stop layer and the second dielectric layer together defining a via channel.

### BRIEF DESCRIPTION OF THE DRAWINGS

A better understanding of the present invention will be realized from the detailed description which follows, taken in conjunction with the accompanying drawings, in which:

FIGS. 1-13 are diagrammatic views of portions of an integrated circuit, and depict successive steps used to fabricate the integrated circuit according to the method of the present invention; and

FIG. 14 is a diagrammatic view of an alternative embodiment of the integrated circuit of FIGS. 1-13, which is made by a method according to the present invention.

### DETAILED DESCRIPTION OF THE INVENTION

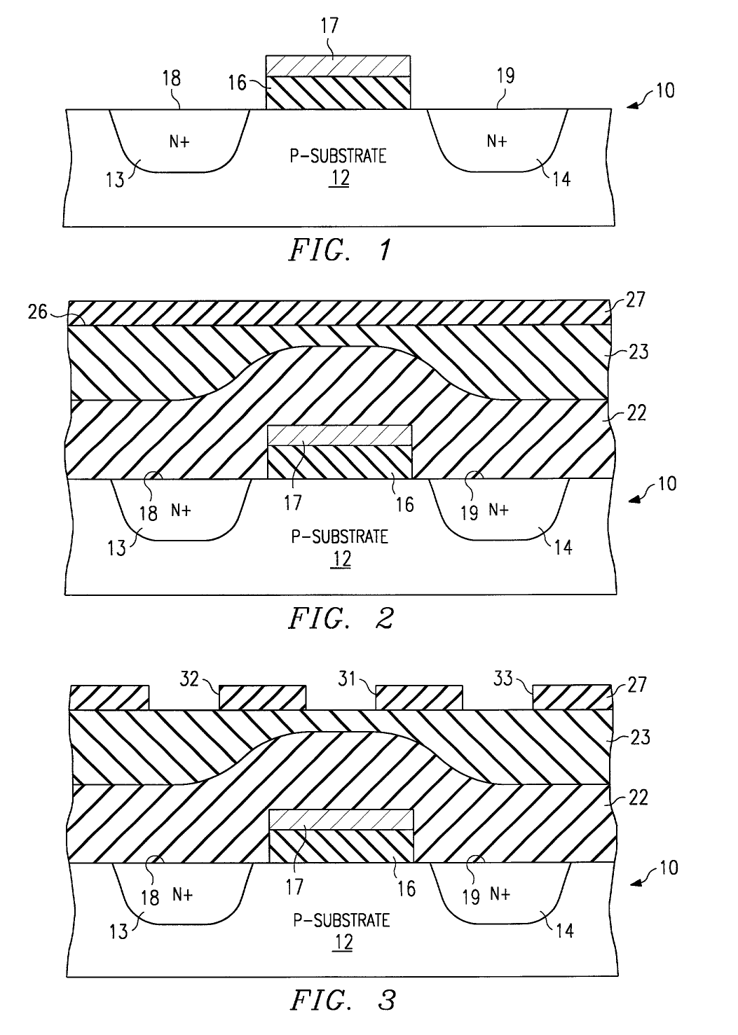

FIG. 1 is a diagrammatic view of a base structure 10 of an integrated circuit. The base structure 10 shown in FIG. 1 is an n-channel MOSFET, but the MOSFET is shown by way of example, and the invention is not limited to this particular base structure. Also, it will be recognized that, for purposes of clarity and convenience, the structure of the integrated circuit is not shown to scale in the drawings.

The base structure 10 of the integrated circuit includes a silicon layer having a p-type semiconductor region 12 and two spaced n+ regions 13 and 14. A silicon dioxide layer 16 is provided on the silicon layer between the n+ regions 13 and 14, and has thereon an n+ doped polysilicon gate electrode 17. The n+ regions 13 and 14 have surface portions 18 and 19 thereon. It is assumed that the upper side of the base structure has been cleaned in a suitable manner which is conventional and known to those skilled in the art.

According to the invention, an interlevel dielectric layer 22 is deposited over the base structure 10 using a known technique, such as applying heat while carrying out low pressure chemical vapor deposition (LPCVD). The resulting layer 22 can be a material conventionally used in the art for an interlevel dielectric layer, such as silicon dioxide. A further interlevel dielectric layer 23 is deposited over the layer 22 using a known technique, such as applying heat while carrying out atmospheric pressure chemical vapor deposition (APCVD). The resulting layer 23 may be the same material as the layer 22, for example silicon dioxide. The layer 23 may, in a conventional manner, be doped with a getterer such as phosphorous, in order to getter alkali ions such as sodium.

A planarization process is then carried out on the side of the dielectric layer 23 opposite from the base structure 10, in order to create a substantially planar surface 26. The planarization may be effected with a process which is conventional and known to those skilled in the art, such as a chemical mechanical polishing technique.

After the surface 26 is created through planarization, an etch stop layer 27 is deposited on the surface 26 of layer 23. A suitable material for the etch stop layer 27 is silicon nitride.

A not-illustrated photoresist pattern is then applied in a conventional manner to the upper side of the etch stop layer 27, after which the etch stop layer 27 is etched using conventional etching techniques, in order to create therethrough a plurality of openings, such as those shown at 31-33 in FIG. 3. The locations of the openings are, of course, determined by the photoresist pattern. In the exemplary embodiment, the openings 31-33 are respectively disposed above the electrode 17 and the surface portions 18-19. After etching, the not-illustrated photoresist pattern is removed from layer 27, and the upper side of layer 27, as well as the openings 31-33 and the exposed portions of surface 26, are thoroughly cleaned using conventional techniques.

Thereafter, a further interlevel dielectric layer 29 is deposited on the upper side of the etch stop layer 27 using a known technique, such as applying heat while carrying out LPCVD. The resulting layer 29 may be of the same material as the dielectric layers 22 and 23, such as silicon dioxide, and may be undoped. A not-illustrated leads trench photoresist pattern is then applied to the upper side of layer 29. A conventional etching technique is thereafter used to etch the dielectric layers 29, 23 and 22. The etch stop layer 27 is resistant to this etching technique. Consequently, the portions of the dielectric layers 22 and 23 which are etched are the portions below the openings 31-33, and the portions of the dielectric layer 29 which are etched are portions determined by the not-illustrated photoresist pattern on layer 29. The photoresist pattern is then removed, and a cleaning process is performed. The resulting structure is shown in FIG. 5.

More specifically, with reference to FIG. 5, via channels 36-38 extend through the layers 22, 23 and 27, coincident with and including the openings 31-33. The via channels 36-38 are sometimes referred to in the art as contact openings. At the lower ends of the via channels 36-38, portions of the upper surfaces of the electrode 17 and the surface portions 18-19 are exposed. In addition, lead trenches 41-43 are formed through the layer 29, to an upper side of the etch stop layer 27. The lead trenches 41-43 are elongate, and extend in a direction perpendicular to the plane of FIG. 5. As evident from FIG. 5, the lead trenches 41-43 have widths larger than the widths of the via channels 36-38. Each of the via channels 36-38 opens at its upper end through the bottom surface of a respective one of the lead trenches 41-43. The dielectric layers 22, 23 and 29 and the etch stop layer 27 are each made of a nonconductive material, and may be referred to collectively as a nonconductive layer.

A barrier layer or liner 46 is then applied so as to cover the upper side of layer 29, and so as to cover exposed surfaces in the trenches 41-43, exposed surfaces in the via channels 36-38, and exposed surface portions of the electrode 17 and the n+ regions 13-14 (surface portions 18-19. The barrier layer 46 serves as a diffusion barrier, for example to keep unwanted materials out of the silicon layer 12, and also promotes adhesion between the layers above and below it. The barrier layer 46 may be a material commonly used for barrier layers, such TiN. The barrier layer 46 is applied using a known technique, such as chemical vapor deposition, or collimated physical vapor deposition.

Pressure is inherently applied to the electrode 17 through the dielectric layer 22. If the electrode 17 is heated prior to application of the barrier layer 46, portions of the electrode 17 may migrate up into the lower ends of the via channels 36-38, which can draw material from other portions of the electrode 17, thereby leaving voids in the structure of the integrated circuit and/or unacceptably thin regions in the electrode 17, both of which cause reduced reliability. To avoid this, the integrated circuit should not be heated significantly from the time the via channels 36-38 are opened until after the barrier layer 46 is in place.

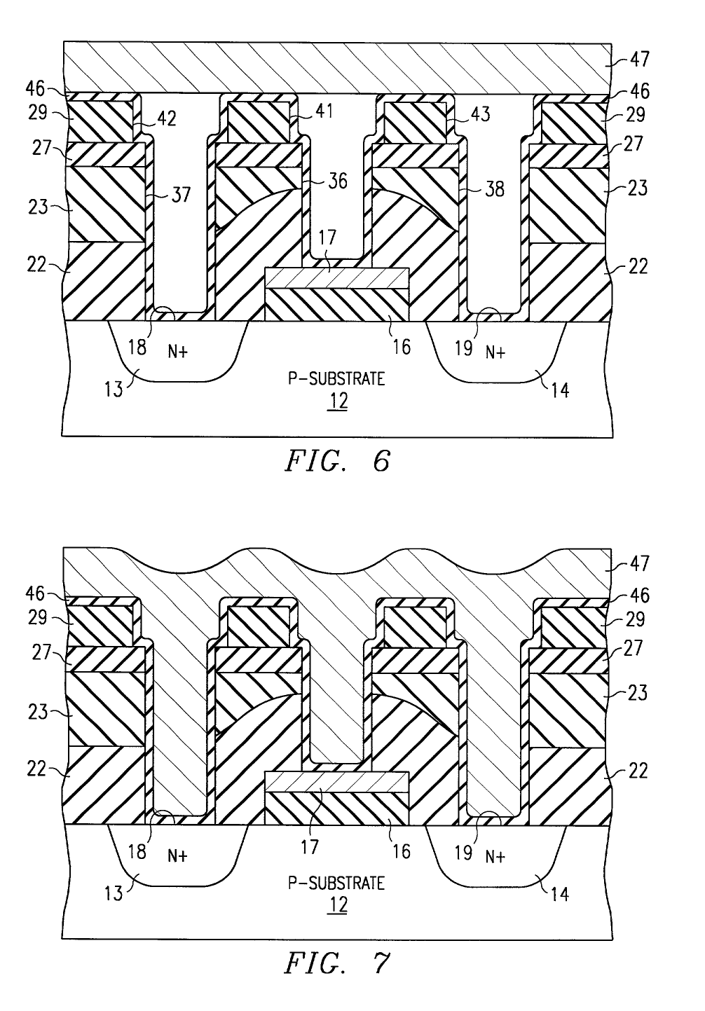

A metal layer 47 is then deposited, and may be aluminum or an aluminum alloy. The resulting structure, which is shown FIG. 6, is then simultaneously subjected to heat and pressure. The amount of heat needed is inversely proportionally to the amount of pressure applied. The necessary relative pressure varies from about 1.0 to about 0.4 as the wafer temperature varies from about 350° C. to about 440° C. In response to the simultaneous application of heat and pressure in this manner, portions of the metal layer 47 are forced into the lead trenches 41-43 and the via channels 36-38, so as to fill the trenches 41-43 and channels 36-38. This is referred to herein as extrusion of the metal layer 47 into the trenches 41-43 and the channels 36-38. At the end of this extrusion, the structure shown in FIG. 6 have changed, and will be as shown in FIG. 7.

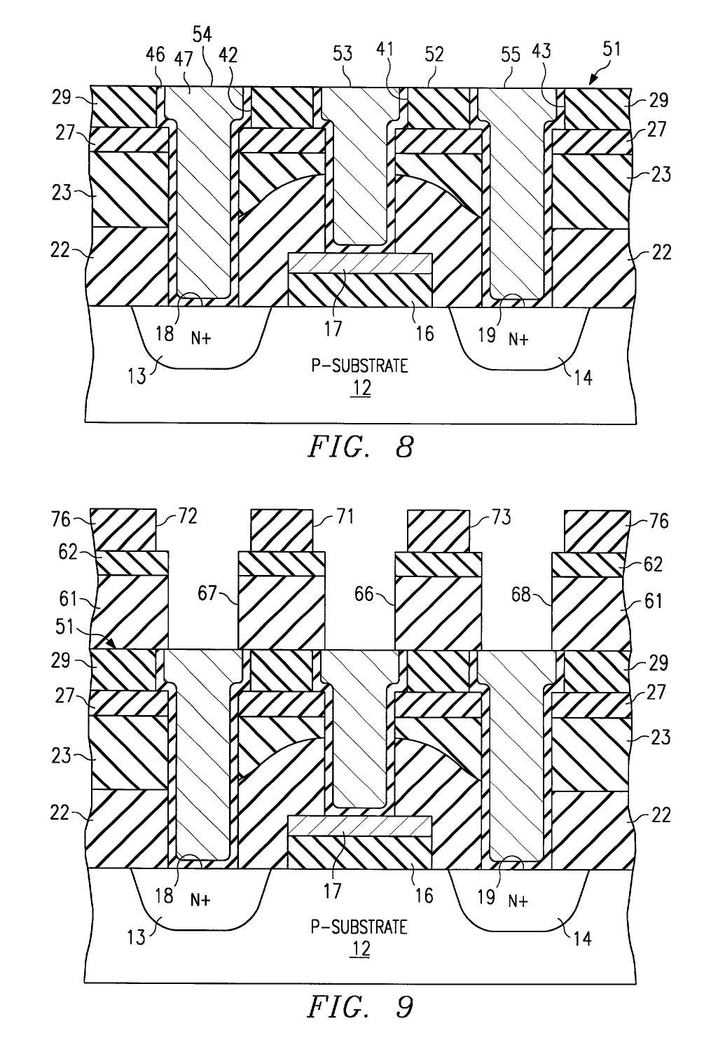

Another planarization procedure is then carried out, and may include a conventional chemical mechanical polishing process. With reference to FIG. 8, this planarization process removes portions of the layers 46 and 47 which are disposed above the upper surface of the dielectric layer 29, so as to define a planar surface 51. The surface 51 includes coplanar portions 52-55, the surface portion 52 being provided on the upper side of the dielectric layer 29, and the portions 53-55 being provided on the upper sides of respective portions of metal layer 46 which remain in the lead trenches 41-43 after the planarization. The portions of the layers 22, 23, 27, 29, 46 and 47 which remain after the planarization may be referred to collectively as a first leads level. The remaining portions of metal layer disposed in the trenches 41-43 are referred to as leads, and the portions disposed in the via channels 36-38 are referred to as vias. The leads and the vias may both be referred to as interconnects.

It is known that, when a liner contacts the top of a metal interconnect, the metal interconnect has better resistance to electromigration than it would if not contacted by a liner. Here, the interconnects formed according to the invention each have liner material in contact with three or four sides thereof. More specifically, it will be noted from FIG. 8 that the material of liner 46 is in contact with three sides of each of the metal leads in the trenches 41-43, namely on the bottom and both sides thereof. Also, the material of liner 46 is in contact with all sides of each of the metal vias in the via channels 36-38.

Using the method according to the present invention, a second leads level may subsequently be formed on the surface 51 of the first leads level. The second leads level is fabricated in a manner which is generally similar to the fabrication of the first leads level. Accordingly, the fabrication of the second leads level is described only briefly, with emphasis on differences from the fabrication of the first leads level. For purposes of the fabrication of the second leads level, the base structure 10 and the first leads level may be collectively considered to be a base structure with a surface 51 on which the second leads level is to be fabricated.

More specifically, with reference to FIG. 9, a further interlevel dielectric layer 61 is deposited on the surface 29, using a known technique such as plasma enhanced chemical vapor deposition (PECVD). An etch stop layer 62 is deposited on the layer 61. The dielectric layer 61 may be made of the same material as the layers 22, 23 and 29, and need not be doped with a getterer. The etch stop layer 62 may be made of the same material as the etch stop layer 27. A photoresist pattern is then applied to the etch stop layer 62, and an etching process is carried out in order etch openings in the etch stop layer 62 but not the dielectric layer 61. The photoresist pattern is then removed and a cleaning process is performed.

In the disclosed embodiment, the first leads level includes two dielectric layers 22 and 23 below the etch stop layer 27, but the second leads level includes only one dielectric layer 61 below the etch stop layer 62. Because of the proximity of the first leads level to the silicon layer 12, and the need to protect the silicon layer from alkali ions, the two dielectric layers 22 and 23 are provided in the first leads level so that the layer 23 can be doped with a getterer such as phosphorous, and the layer 22 can be undoped. In contrast, in the second leads level a getterer is not needed, and the single undoped dielectric layer 61 is sufficient. If the etch stop layer 27 in the first leads level had barrier properties, for example silicon nitride, it would be possible to omit the dielectric layer 22 in the first leads level and to optimize the doping in the dielectric layer 23 with respect to the etch selectivity to the etch stop layer 27 only. That is, layer 23 would not have to be a good getterer as well.

A further interlevel dielectric layer 76 is then deposited on the etch stop layer 62, using a known technique such as PECVD. Then, a photoresist pattern is applied to layer 76, and an etching process is carried out in order to etch the dielectric layers 76 and 61 in a manner which creates via channels 66-68 extending through layers 61 and 62 from the surface 51 to the top side of etch stop layer 62, and which creates lead trenches 71-73 through the dielectric layer 76. While the via channels 36-38 in a first leads level are sometimes referred to as contact openings, as mentioned above, the via channels 66-68 in a second or higher leads level are sometimes referred to in the art as via openings. To avoid confusion here, the common term “via channel” is used.

The lead trenches 71-73 are wider than the via channels 66-68, and the upper end of each via channel 66-68 opens through the bottom surface of a respective one of the lead trenches 71-73. Because of the planar surface 51, each of the via channels 66-68 may be located directly over one of the via channels 36-38, as shown in FIG. 9. According to the invention, this is true even when the interconnect widths are less than about 0.25 micron. In contrast, such a vertical alignment is avoided when known plug technology is used to form interconnects with widths less than about 0.25 micron, because of reliability problems.

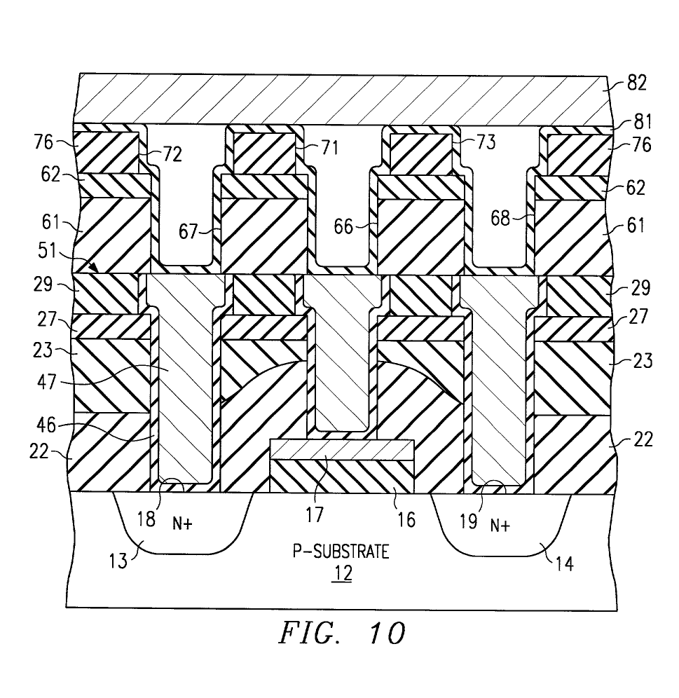

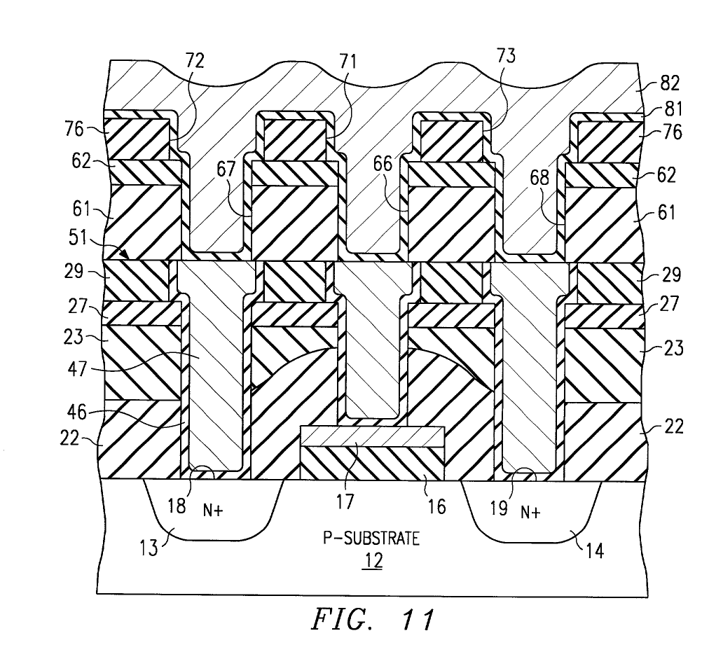

The photoresist pattern is subsequently removed, and a conventional cleaning process is carried out. Thereafter, with reference to FIG. 10, a barrier layer 81 is deposited on the exposed surfaces of the layer 76, the lead trenches 71-73, the via openings 66-68, and the exposed portions of surface 51. A metal layer 82 is then deposited, as shown in FIG. 10.

Heat and pressure are then simultaneously applied in order to extrude the metal layer 82 into the lead trenches 71-73 and into the via channels 66-68, the resulting structure being shown in FIG. 11.

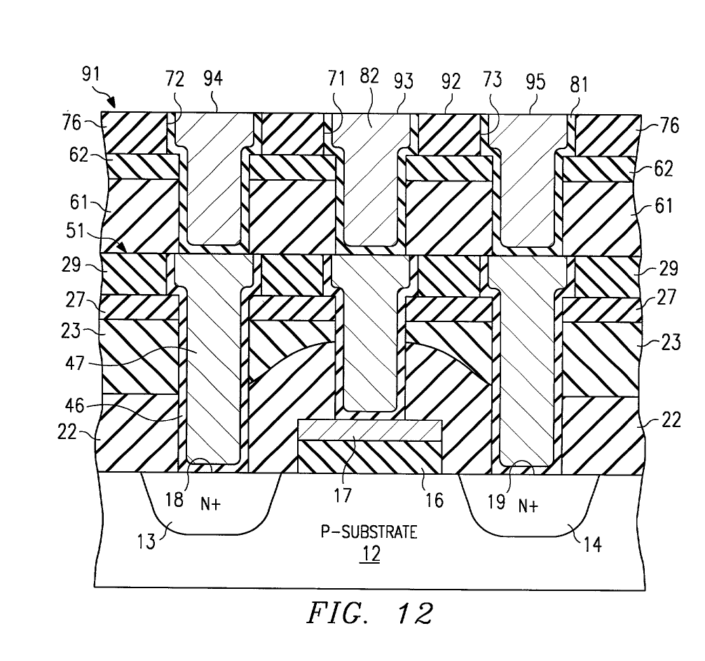

A planarization process is then carried out, which may be a conventional chemical mechanical polishing process, in order to remove portions of the layers 81 and 82 above the top of the dielectric layer 76. In particular, with reference to FIG. 12, the planarization process creates a planar surface 91 that includes coplanar surface portions 92-95, the surface portion 92 being provided on the upper side of the layer 76, and the surface portions 93-95 being provided on respective portions of the metal layer 82 which remain in the lead trenches 71-73 after the planarization. The second leads level thus includes the portions of layers 61, 62, 76, 81 and 82 which remain after planarization.

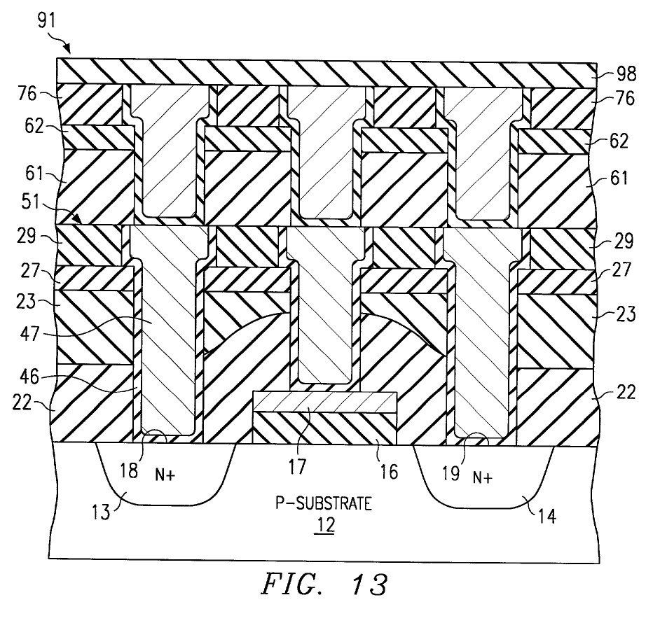

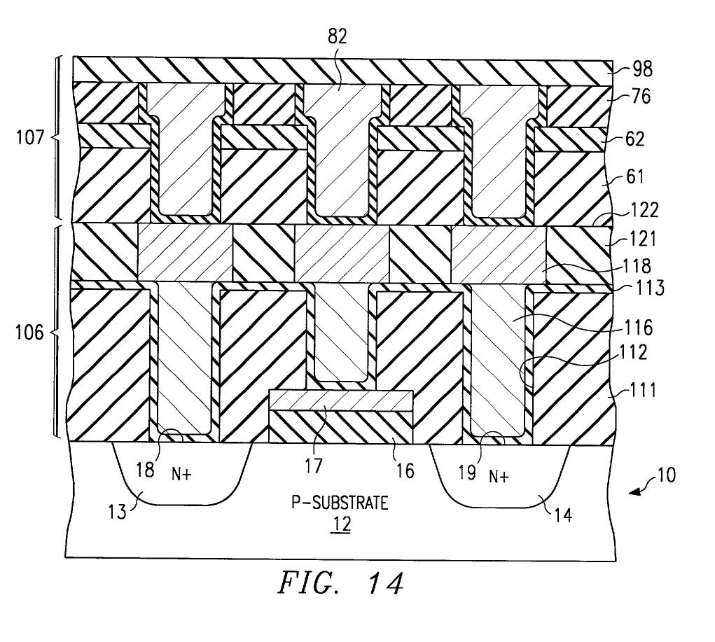

A third leads level could optionally be formed on the surface 91 of the second leads level. The third leads level would be similar to the second leads level, and would be fabricated using substantially the same steps described above for the second leads level. Thereafter, a fourth leads level could optionally be fabricated on the third leads level, and so on. However, for purposes of the present disclosure, it is assumed that the second leads level in FIG. 12 is the uppermost and final leads level. As shown in FIG. 13, a passivating overcoat 98 is applied to the surface 91 of the second leads level. The passivating overcoat 98 may be made of a material conventionally used for passivating overcoats, such as silicon nitride, oxy-nitride, or oxide-nitride. The purpose of the passivating overcoat is to protect the resulting device from chemical contaminants, such as alkali ions, and from mechanical damage, such as scratching during subsequent handling.

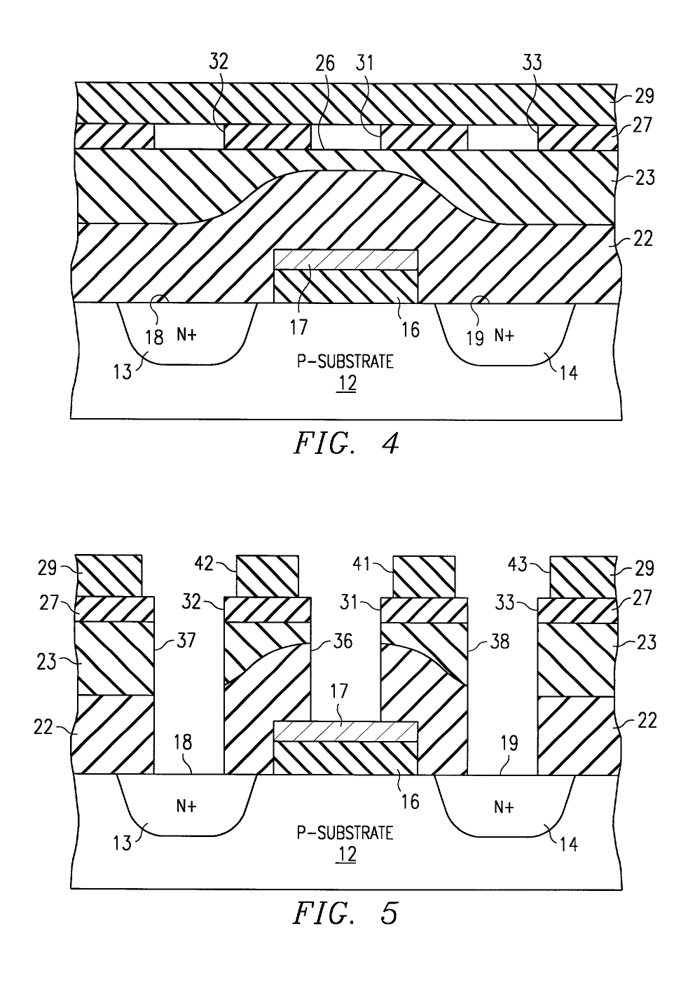

FIG. 14 is a diagrammatic view of an alternative embodiment of the integrated circuit shown in FIGS. 1-13. The integrated circuit of FIG. 14 includes a base structure 10, which is identical to the base structure of the integrated circuit of FIGS. 1-13. In particular, the base structure 10 includes a silicon layer having a p-type semiconductor region 12 and two spaced n+ regions 13 and 14, a silicon dioxide layer 16 provided on the silicon layer between the n+ regions 13 and 14, a polysilicon gate electrode 17 on the layer 16, and surface portions 18 and 19 on the regions 13 and 14. The integrated circuit of FIG. 14 has formed on the base structure 10 a first leads level 106, which has on it a second leads level 107.

The first leads level 106 is fabricated by a known tungsten-plug process. More specifically, an interlevel dielectric layer 111 is deposited on the base structure 10. The resulting layer 111 may be a material such as silicon dioxide. A not-illustrated photoresist is then applied to the upper side of the dielectric layer 111, and a plurality of via channels are etched therethrough, one of which is shown at 112. The photoresist is then removed, and a cleaning process is carried out. A barrier layer or liner 113 is then deposited, so as to cover the top surface of the dielectric layer 111, exposed surfaces of the dielectric layer 111 within the via channels 112, and exposed surface portions of the gate electrode 17 and the regions 13 and 14 of the base structure 10. A layer of tungsten is then deposited on the upper side of the barrier layer 113, after which the tungsten layer is etched down until only the tungsten material within the via channels remains. In particular, the remaining tungsten material defines within each via channel a plug, one of which is shown at 116, the plugs having their upper ends approximately flush with the top surface of the barrier layer 113, as shown in FIG. 14.

A layer of aluminum is then deposited on the exposed surfaces of the layer 113 and the plugs 116. A not-illustrated photoresist is then applied, and unwanted portions of the aluminum layer are etched away in order to leave elongate aluminum leads, one of which is shown at 118. The leads 118 are in electrical contact with the upper ends of the plugs 116. The spaces etched between the aluminum leads 118 are then filled with a dielectric material 121, which may be silicon dioxide. Thereafter, the upper side of the structure is planarized, for example using a known CMP technique, in order to create a substantially planar surface 122.

The second leads level 107 is then formed on the planar surface 122 of the first leads level 106. The second leads level 107 is identical to the second leads level shown in FIGS. 12-13. Accordingly, elements of the second leads level 107 are designated with the same reference numerals as in FIGS. 12 and 13, and the process for making the second leads level 107 is not described again in detail here.

After forming the second leads level 107, a passivating overcoat 98 is applied on top of the second leads level 107. The passivating overcoat 98 is identical to the passivating overcoat shown in the embodiment of FIG. 13, and is identified with the same reference numeral.

The present invention provides numerous technical advantages. One such technical advantage is that interconnects with widths less than 0.5 micron can be fabricated, and will reliably resist electromigration failures. A further technical advantage is that the method according to the invention involves fewer overall process steps than conventional methods such as W-plug technology, which reduces the cost and increases reliability. One facet of this, resulting from the use of damascence, is that each leads level can be fabricated according to the invention without any metal etch step. This leads to the further advantage that the method according to the invention can be used with a wider range of metals than conventional W-plug techniques, because W-plug technology is limited to metals which can be etched, whereas the invention can be used with metals that cannot be etched. For example, in addition to aluminum and aluminum alloys, metals such as copper can be used in a method according to the invention.

Further advantages result from the use of extrusion. Extrusion is known to reduce the incidence of electromigration failures, while avoiding a need to change materials (by using a material other than aluminum or an aluminum alloy). Further, it in known that leads have improved reliability if they are contacted by a liner material on the top side, and the method according to the invention produces leads and vias which contact liner material on three or four sides thereof. Damascence is known to inherently provide better process control than W-plug technology, and the method according to the invention thus realizes better process control through the use of damascence.

Yet another advantage is that the passivating overcoat is applied to a planarized surface, which reduces the likelihood that the overcoat will have flaws of the type that result from applying the overcoat over the rough typography generated by the conventional process. Still another advantage is that the vias in adjacent lead layers can be vertically aligned with each other, even when the interconnects have widths less than about 0.25 micron, due to planarization of the surface on which a leads level is to be fabricated in accord with the method of the present invention. Another advantage results from the provision of a technique for double damascence, in which a single etch step is used to create both via channels and lead trenches in a dielectric material.

Although one embodiment has been illustrated and described in detail, it should be understood that various changes, substitutions and alterations can be made without departing from the scope of the present invention. For example, the foregoing disclosure teaches that each leads level is fabricated according to the present invention, but it would be possible to fabricate selected lead levels according to the invention and other lead levels using conventional techniques. For example, the first lead level might be fabricated with conventional techniques, and subsequent lead levels might be fabricated using the method according to the invention. As another example, the foregoing disclosure illustrates and describes an exemplary arrangement of two lead levels on a base structure having an electrode, but it will be recognized that there are many variations of this arrangement which fall within the scope of the present invention. As yet another example, the foregoing disclosure discusses certain specific materials which may be used in the disclosed method according to the invention, but it will be recognized that there are other materials which are equally suitable for use in the inventive method. Other changes, substitutions and alterations are also possible without departing from the spirit and scope of the present invention, as defined by the following claims.

What is claimed is:

1. A method for making an integrated circuit, comprising the steps of:
fabricating on a substantially planar surface of a base structure a nonconductive layer having in a side thereof opposite from the base structure a lead trench which is spaced from the base structure, and having a via channel which opens at one end into the lead trench and which opens at the other end through a side of the nonconductive layer nearest the base structure;
applying on a side of the nonconductive layer opposite from the base structure a liner, the liner covering exposed surfaces in the lead trench and the via channel;
applying on a side of the liner opposite from the base structure a metal layer;
simultaneously applying heat and pressure so as to cause the metal layer to be extruded into the lead trench and the via opening; and
thereafter carrying out a planarizing step which creates a substantially planar first surface portion on a side of the nonconductive layer opposite from the base structure, which removes portions of the liner and the metal layer on a side of the first surface portion remote from the base structure, and which creates on a portion of the metal layer disposed in the lead trench a second surface portion which is substantially coplanar with the first surface portion.

2. A method according to claim 1, including after said planarizing step the step of applying a passivating overcoat to a planar surface which includes the coplanar first and second surface portions.

3. A method according to claim 1, wherein said fabricating step is carried out by forming a first dielectric layer, by thereafter forming on the first dielectric layer an etch stop layer, by thereafter etching in the etch stop layer an opening which forms part of the via channel, by thereafter depositing on the etch stop layer a second dielectric layer, and by thereafter etching the first and second dielectric layers so as to create in the second dielectric layer the lead trench and so as to create in the first dialectic layer an opening therethrough which forms a portion of the via channel.

4. A method according to claim 1, wherein said fabricating step includes the steps of forming a first dielectric layer which is undoped, thereafter forming on the first dielectric layer a second dielectric layer which is doped with a getterer, thereafter forming on the second dielectric layer an etch stop layer, thereafter etching the etch stop layer to create therein an opening which serves as a portion of the via channel, thereafter forming on the etch stop layer a third dielectric layer, and thereafter etching the first, second and third dielectric layers so as to create in the third dielectric layer the lead trench and so as to create through the first and second dielectric layers an opening which is a portion of the via channel.

5. A method according to claim 1, wherein said fabricating step includes the step of forming the via channel to have a width which is less than 0.5 micron.

6. A method according to claim 1, wherein said fabricating step includes the step of forming the lead trench so that a transverse dimension of the lead trench is less than 0.5 micron.

7. A method according to claim 1, wherein said planarizing step includes a chemical mechanical polishing step.

8. A method for making an integrated circuit, comprising the steps of:
fabricating on a first planar surface of a base structure a first non-conductive layer having in a side thereof opposite from the base structure a first lead trench which is spaced from the base structure, and having a first via channel which opens at one end into the first lead trench and which opens at the other end through a side of the first nonconductive layer nearest the base structure;
applying on the side of the first nonconductive layer opposite from the base structure a first liner, the first liner covering exposed surfaces in the first lead trench and the first via channel;
applying on a side of the first liner opposite from the base structure a first metal layer;
simultaneously applying heat and pressure so as to cause the first metal layer to be extruded into the first lead trench and the first via channel;
thereafter carrying out a first planarizing step which creates a substantially planar first surface portion on a side of the first nonconductive layer opposite from the base structure, which removes portions of the first liner and the first metal layer on a side of the first surface portion remote from the base structure, and which creates on a portion of the first metal layer disposed in the first lead trench a second surface portion which is substantially coplanar with the first surface portion;
fabricating on a second planar surface which includes the first and second surface portions a second nonconductive layer having in a side thereof opposite from the second planar surface a second lead trench which is spaced from the planar surface, and having a second via channel which opens at one end into the second lead trench and which opens at the other end through a side of the second nonconductive layer facing the second planar surface.
applying on a side of the second nonconductive layer opposite from the second planar surface a second liner, the second liner covering exposed surfaces in the second lead trench and the second via channel;
applying on a side of the second liner opposite from the second planar surface a second metal layer;
simultaneously applying heat and pressure so as to cause the second metal layer to be extruded into the second lead trench and the second via channel; and
thereafter carrying out a second planarizing step which creates a substantially planar third surface portion on a side of the second nonconductive layer opposite from the second planar surface, which removes portions of the second liner and the second metal layer on a side of the third surface portion remote from the second planar surface, and which creates on a portion of the second metal layer disposed in the second lead trench a fourth surface portion which is substantially coplanar with the third surface portion.

9. A method according to claim 8, wherein the second via channel is substantially aligned with the first via channel.

10. An integrated circuit, made according to a method which includes the steps of:
fabricating on a surface of a base structure a nonconductive layer having in a substantially planar side thereof opposite from the base structure a lead trench which is spaced from the base structure, and having a via channel which opens at one end into the lead trench and which opens at the other end through a side of the nonconductive layer nearest the base structure;
applying on a side of the nonconductive layer opposite from the base structure a liner, the liner covering exposed surfaces in the lead trench and the via channel;
applying on a side of the liner opposite from the base structure a metal layer;
simultaneously applying heat and pressure so as to cause the metal layer to be extruded into the lead trench and the via opening; and
thereafter carrying out a planarizing step which creates a substantially planar first surface portion on a side of the nonconductive layer opposite from the base structure, which removes portions of the liner and the metal layer on a side of the first surface portion remote from the base structure, and which creates on a portion of the metal layer disposed in the lead trench a second surface portion which is substantially coplanar with the first surface portion.

11. A method for making an integrated circuit, comprising the steps of:
fabricating on a base structure a first non-conductive layer having therethrough a first via channel;
providing a conductive plug which extends through the first via channel;
fabricating a metal lead over the first non-conductive layer and the conductive plug, the conductive plug having its upper end electrically coupled to the metal lead;
filling regions adjacent the metal lead with a non-conductive material;
carrying out a planarizing step to create on the metal lead and the non-conductive material a substantially planar surface;
fabricating on the planar surface a second nonconductive layer having in a side thereof opposite from the planar surface a lead trench which is spaced from the planar surface, and having a second via channel which opens at one end into the lead trench and which opens at the other end through a side of the second nonconductive layer facing the planar surface.
applying on a side of the second nonconductive layer opposite from the planar surface a liner, the liner covering exposed surfaces in the lead trench and the second via channel;
applying on a side of the liner opposite from the planar surface a metal layer;
simultaneously applying heat and pressure so as to cause the metal layer to be extruded into the lead trench and the second via channel; and
thereafter carrying out a further planarizing step which creates a substantially planar first surface portion on a side of the second nonconductive layer opposite from the planar surface, which removes portions of the liner and the metal layer on a side of the first surface portion remote from the planar surface, and which creates on a portion of the metal layer disposed in the lead trench a second surface portion which is substantially coplanar with the first surface portion.

12. A method according to claim 11, including after said step of fabricating the first non-conductive layer and before said step of providing the conductive plug, the step of applying on a side of the first non-conductive layer remote from the base structure a further liner, the further liner covering exposed surfaces of the first via channel and the base structure.

13. A method according to claim 11, wherein said step of fabricating the second non-conductive layer is carried out by forming a first dielectric layer, by thereafter forming on the first dielectric layer an etch stop layer, by thereafter etching in the etch stop layer an opening which forms part of the second via channel, by thereafter depositing on the etch stop layer a second dielectric layer, and by thereafter etching the first and second dielectric layers so as to create in the second dielectric layer the lead trench and so as to create in the first dialectic layer an opening therethrough which forms a portion of the second via channel.

14. A method for making an integrated circuit, comprising the steps of:
forming a first dielectric layer on a surface of a base structure;
forming on the first dielectric layer an etch stop layer;
forming in the etch stop layer an opening;
forming on the etch stop layer a second dielectric layer; and
etching the first and second dielectric layers so as to create in the second dielectric layer a lead trench and so as to create through the first dielectric layer an opening aligned with the opening through the etch stop layer, the openings through the etch stop layer and the second dielectric layer together defining a via channel.

15. A method according to claim 1, wherein said step of forming the first dielectric layer includes the steps of:
forming on the surface of the base structure a third dielectric layer which is undoped; and
forming on the third dielectric layer a fourth dielectric layer which is doped with a getterer;
the first dielectric layer including the third and fourth dielectric layers.

16. A method according to claim 1, wherein said step of forming the opening in the etch stop layer includes the step of etching the etch stop layer.
